(19) United States
(12) Patent Application Publication
(10) Pub. No.: US 2026/0150183 A1
(43) Pub. Date: May 28, 2026

(54) ELECTRONIC DEVICE AND METHOD OF SUPPRESSING SIGNAL NOISE GENERATED BY BUCK-BOOST CIRCUIT

(71) Applicants: INVENTEC (PUDONG) TECHNOLOGY CORPORATION, Shanghai (CN); INVENTEC CORPORATION, Taipei City (TW)

(72) Inventor: Chih-Chien CHIANG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/236,721

(22) Filed: Jun. 12, 2025

(30) Foreign Application Priority Data
Nov. 25, 2024 (CN) 202411703336.4

(51) Int. Cl. H05K 1/02; H05K 1/11; H05K 7/04

(52) U.S. Cl. CPC H05K 1/0231; H05K 1/115; H05K 7/04; H05K 2201/10015; H05K 2201/10522

(57) ABSTRACT

An electronic device configured for a buck-boost circuit to be disposed thereon, and includes a chassis, a circuit board and noise suppression capacitors. The circuit board is disposed in the chassis, and is configured for the buck-boost circuit to be disposed thereon. The circuit board has a power circuit structure having power conductive vias. The noise suppression capacitors are disposed on at least one side of the power circuit structure. The power circuit structure provides at least a part of the noise suppression capacitors located adjacent to the power conductive vias, and provides at least a part of the noise suppression capacitors located away from the power conductive vias. A distance between any two adjacent noise suppression capacitors located away from the power conductive vias is configured to be less than or equal to one-eighth of a wavelength of a signal noise generated by the buck-boost circuit.

### CROSS-REFERENCE TO RELATED APPLICATIONS

This non-provisional application claims priority under 35 U.S.C. § 119(a) on Patent Application No(s). 202411703336.4 filed in China, on Nov. 25, 2024, the entire contents of which are hereby incorporated by reference.

### BACKGROUND OF THE INVENTION

### Technical Field of the Invention

The invention relates to an electronic device and a method of suppressing signal noise generated by buck-boost circuit, more particularly to an electronic device having noise suppression capacitors and a method of suppressing signal noise generated by buck-boost circuit.

### Description of the Related Art

Recently, according to various requirements, designs of circuit boards in electronic products have become increasingly complicated. Therefore, a signal noise generated by electronic components disposed on the circuit boards is gradually increased, thereby adversely affecting an operation of the electronic components.

Generally, manufacturers may additionally install absorbing sheets which can suppress the signal noise generated by the circuit boards. However, the additional absorbing sheets not only increase the manufacturing cost of the electronic products, but also disturb the arrangement of the circuit boards. Therefore, lowering an intensity of the signal noise generated by electronic products effectively is one of the key issues that researchers need to address.

### SUMMARY OF THE INVENTION

The invention provides an electronic device and a method of suppressing signal noise generated by buck-boost circuit so as to lower an intensity of the signal noise generated by an electronic device effectively.

One embodiment of the invention provides an electronic device configured for a buck-boost circuit to be disposed thereon. The electronic device includes a chassis, a circuit board and a plurality of noise suppression capacitors. The circuit board is disposed in the chassis, and is configured for the buck-boost circuit to be disposed thereon. The circuit board has a power circuit structure. The power circuit structure has a plurality of power conductive vias. The plurality of noise suppression capacitors are disposed on at least one side of the power circuit structure. The power circuit structure provides at least a part of the plurality of noise suppression capacitors located adjacent to the plurality of power conductive vias, respectively, and provides at least a part of the plurality of noise suppression capacitors located away from the plurality of power conductive vias. A distance between any adjacent two of the plurality of noise suppression capacitors located away from the plurality of power conductive vias is configured to be less than or equal to one-eighth of a wavelength of a signal noise generated by the buck-boost circuit.

Another embodiment of the invention provides a method of suppressing signal noise generated by buck-boost circuit including disposing at least a part of a plurality of noise suppression capacitors on a portion of a power circuit structure adjacent to a plurality of power conductive vias of a circuit board and disposing at least a part of the plurality of noise suppression capacitors on a portion of the power circuit structure located away from the plurality of power conductive vias. A distance between any adjacent two of the plurality of noise suppression capacitors located away from the plurality of power conductive vias is less than or equal to one-eighth of a wavelength of a signal noise generated by the buck-boost circuit.

According to the electronic device and the method of suppressing noise generated by buck-boost circuit disclosed in the above embodiment, the power circuit structure 121 provides at least a part of the noise suppression capacitors located adjacent to the power conductive vias, respectively, and provides at least a part of the noise suppression capacitors located away from the power conductive vias. The distance between any two adjacent noise suppression capacitors located away from the power conductive vias is, for example, less than or equal to one-eighth of the wavelength of the signal noise generated by the buck-boost circuit. Therefore, intensity of the signal the noise of the electronic device can be effectively lowered. In this way, the desired performance for suppressing signal noise is allowed to be realized while preventing short circuit or open circuit with less noise suppression capacitors 13, thereby saving the manufacturing cost of the electronic device.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a plane view of an electronic device in accordance with an embodiment of the invention;

FIG. 2 is a graph showing an intensity of the signal noise of the electronic device in FIG. 1; and

FIG. 3 is a flow chart showing a method of suppressing a noise generated by a buck-boost circuit in accordance with an embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

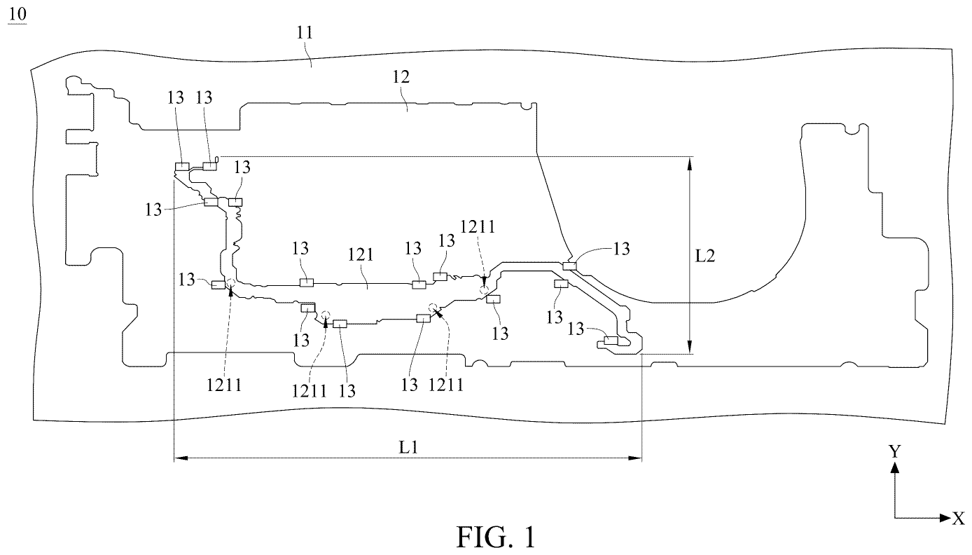

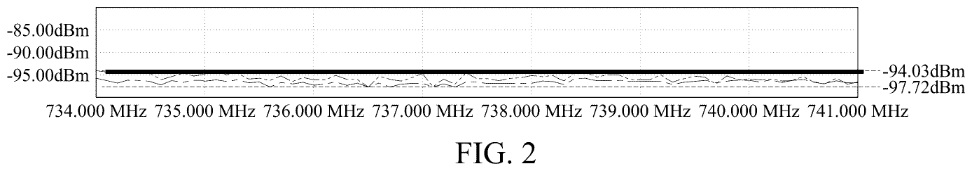

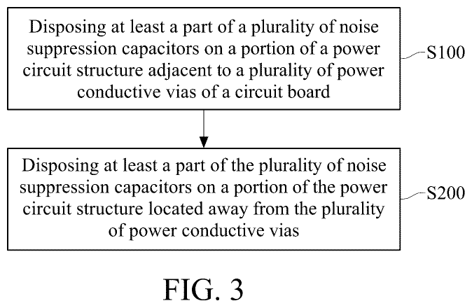

Please refer to FIG. 1 and FIG. 3, where FIG. 1 is a plane view of an electronic device 10 in accordance with an embodiment of the invention, FIG. 2 is a graph showing an intensity of the signal noise of the electronic device 10 in FIG. 1, and FIG. 3 is a flow chart showing a method of suppressing a noise generated by a buck-boost circuit in accordance with an embodiment of the invention.

In this embodiment, the electronic device 10 is configured for a buck-boost circuit (not shown) to be disposed, and includes a chassis 11, a circuit board 12 and a plurality of noise suppression capacitors 13. The circuit board 12 is disposed in the chassis 11, and a side of the circuit board 12 is configured for the buck-boost circuit to be disposed thereon. The other side of the circuit board 12 has a power circuit structure 121, but the invention is not limited thereto. The power circuit structure 121 has a plurality of power conductive vias 1211. The power conductive vias 1211 are conductive through vias corresponding to power sources, a memories and universal serial buses (USB). A length L1 of the power circuit structure 121 along an X-axis direction is, for example, 130 millimeters, and a length L2 of the power circuit structure 121 along a Y-axis direction is, for example, 76 millimeters.

According to an arrangement of other electronic components disposed on the circuit board 12, a side of the power circuit structure 121 provides at least a part of the noise suppression capacitors 13 to be disposed thereon, and two opposite sides of the power circuit structure 121 provides at least a part of the noise suppression capacitors 13 to be disposed thereon. Similarly, according to an arrangement of other electronic components disposed on the circuit board 12, an end of the power circuit structure 121 provides at least a part (e.g. one) of the noise suppression capacitors 13 to be disposed thereon, and the other end of the power circuit structure 121 provides at least a part (e.g. two) of the noise suppression capacitors 13 to be disposed. The noise of the signals generated by the buck-boost circuit can be suppressed via the noise suppression capacitors 13 having a great impedance reflection.

The power circuit structure 121 provides at least a part of the noise suppression capacitors 13 located adjacent to the power conductive vias 1211, respectively, and provides at least a part of the noise suppression capacitors 13 located away from the power conductive vias 1211. A distance between any two adjacent noise suppression capacitors 13 located away from the power conductive vias 1211 is, for example, less than or equal to one-eighth of a wavelength of the signal noise generated by the buck-boost circuit. Accordingly, for example, with respect to a signal noise whose frequency ranging from 734 MHz to 741 MHz, the intensity of the signal noise can be lowered from −88.05 dBm to −94.03 dBm or even to −97.72 dBm.

For example, when the noise frequency generated by the buck-boost circuit is 800 MHz (i.e. the wavelength of the signal noise is, for example, 16 centimeters), the distance between any two adjacent noise suppression capacitors 13 located away from the power conductive vias 1211 is less than or equal to 2 centimeters (i.e. one-eighth of the aforementioned wavelength of the signal noise). In addition, according to the resonance frequency between the noise suppression capacitors 13 and the signal noise, the noise suppression capacitors 13 having a capacitance of, for example, 180 picofarads can be adopted.

In this embodiment, the power circuit structure 121 provides at least a part of the noise suppression capacitors 13 located adjacent to the power conductive vias 1211, respectively, and provides at least a part of the noise suppression capacitors 13 located away from the power conductive vias 1211. The distance between any two adjacent noise suppression capacitors 13 located away from the power conductive vias 1211 is, for example, less than or equal to one-eighth of the wavelength of the signal noise generated by the buck-boost circuit. Therefore, the intensity of the signal noise of the electronic device 10 can be effectively lowered. In this way, the desired performance for suppressing signal noise is allowed to be realized while preventing short circuit or open circuit with less noise suppression capacitors 13, thereby saving the manufacturing cost of the electronic device 10.

In this embodiment, a side of the circuit board 12 is configured for the buck-boost circuit to be disposed thereon, and the other side of the circuit board 12 has the power circuit structure 121, but the invention is not limited thereto. In other embodiments, according to the arrangement of other electronic components disposed on the circuit board, the buck-boost circuit and the power circuit structure may be disposed on the same side of the circuit board.

In this embodiment, a side of the power circuit structure 121 provides at least a part of the noise suppression capacitors 13 to be disposed thereon, and two opposite sides of the power circuit structure 121 provides at least a part of the noise suppression capacitors 13 to be disposed thereon, but the invention is not limited thereto. In other embodiments, according to the arrangement of other electronic components disposed on the circuit board, a side of the power circuit structure may provide all of the noise suppression capacitors to be disposed thereon, or two opposite sides of the power circuit structure may provide all of the noise suppression capacitors to be disposed thereon.

In this embodiment, an end of the power circuit structure 121 provides one of the noise suppression capacitors 13 to be disposed thereon, and the other end of the power circuit structure 121 provides two of the noise suppression capacitors 13 to be disposed thereon, but the invention is not limited thereto. In other embodiments, according to the arrangement of other electronic components disposed on the circuit board, each of two opposite ends of the power circuit structure provides one of the noise suppression capacitors to be disposed thereon, or each of two opposite ends of the power circuit structure provides two of the noise suppression capacitors to be disposed thereon.

In this embodiment, the capacitance of the noise suppression capacitors 13 is 180 picofarads, but the invention is not limited thereto. In other embodiments, according to the resonance frequency between the noise suppression capacitors and the signal noise, the noise suppression capacitors having a capacitance of, for example, 150 picofarads may be adopted.

In this embodiment, the method of suppressing the signal noise generated by the buck-boost circuit according to this embodiment includes, but is not limited thereto, following steps. A step S100 is, firstly, performed to dispose at least a part of the noise suppression capacitors 13 on a portion of the power circuit structure 121 adjacent to the power conductive vias 1211 of a circuit board 12. A step S200 is, then, performed to dispose at least a part of the noise suppression capacitors 13 on a portion of the power circuit structure 121 located away from the power conductive vias 1211. The order of the step S100 and the step S200 is not limited to the aforementioned sequence. In addition, the distance between any two adjacent noise suppression capacitors 13 located away from the power conductive vias 1211 is, for example, less than or equal to one-eighth of the wavelength of the signal noise generated by the buck-boost circuit. Accordingly, the intensity of the signal noise generated by the buck-boost circuit can be lowered.

According to the electronic device and the method of suppressing signal noise generated by buck-boost circuit disclosed in the above embodiment, the power circuit structure 121 provides at least a part of the noise suppression capacitors located adjacent to the power conductive vias, respectively, and provides at least a part of the noise suppression capacitors located away from the power conductive vias. The distance between any two adjacent noise suppression capacitors located away from the power conductive vias is, for example, less than or equal to one-eighth of the wavelength of the signal noise generated by the buck-boost circuit. Therefore, intensity of the signal the noise of the electronic device can be effectively lowered. In this way, the desired performance for suppressing signal noise is allowed to be realized while preventing short circuit or open circuit with less noise suppression capacitors 13, thereby saving the manufacturing cost of the electronic device.

It will be apparent to those skilled in the art that various modifications and variations can be made to the invention. It is intended that the specification and examples be considered as exemplary embodiments only, with the scope of the invention being indicated by the following claims.

What is claimed is:

1. An electronic device, configured for a buck-boost circuit to be disposed thereon, and the electronic device comprising:
a chassis;
a circuit board, disposed in the chassis and configured for the buck-boost circuit to be disposed thereon, wherein the circuit board has a power circuit structure, and the power circuit structure has a plurality of power conductive vias; and
a plurality of noise suppression capacitors, disposed on at least one side of the power circuit structure, wherein the power circuit structure provides at least a part of the plurality of noise suppression capacitors located adjacent to the plurality of power conductive vias, respectively, and provides at least a part of the plurality of noise suppression capacitors located away from the plurality of power conductive vias, and a distance between any adjacent two of the plurality of noise suppression capacitors located away from the plurality of power conductive vias is configured to be less than or equal to one-eighth of a wavelength of a signal noise generated by the buck-boost circuit.

2. The electronic device according to claim 1, wherein each of two opposite ends of the power circuit structure provides at least a part of the plurality of noise suppression capacitors to be disposed thereon.

3. The electronic device according to claim 1, wherein a capacitance of the plurality of noise suppression capacitors is 180 picofarads (pF).

4. The electronic device according to claim 1, wherein a capacitance of the plurality of noise suppression capacitors is 150 picofarads (pF).

5. The electronic device according to claim 1, wherein the distance between any adjacent two of the plurality of noise suppression capacitors located away from the plurality of power conductive vias is less than or equal to 2 centimeters.

6. A method of suppressing signal noise generated by buck-boost circuit, comprising:
disposing at least a part of a plurality of noise suppression capacitors on a portion of a power circuit structure adjacent to a plurality of power conductive vias of a circuit board; and
disposing at least a part of the plurality of noise suppression capacitors on a portion of the power circuit structure located away from the plurality of power conductive vias;
wherein a distance between any adjacent two of the plurality of noise suppression capacitors located away from the plurality of power conductive vias is less than or equal to one-eighth of a wavelength of a signal noise generated by the buck-boost circuit.

7. The method of suppressing noise generated by buck-boost circuit according to claim 6, wherein each of two opposite ends of the power circuit structure provides at least a part of the plurality of noise suppression capacitors to be disposed thereon.

8. The method of suppressing noise generated by buck-boost circuit according to claim 6, wherein a capacitance of the plurality of noise suppression capacitors is 180 picofarads (pF).

9. The method of suppressing noise generated by buck-boost circuit according to claim 6, wherein a capacitance of the plurality of noise suppression capacitors is 150 picofarads (pF).

10. The method of suppressing noise generated by buck-boost circuit according to claim 6, wherein the distance between any adjacent two of the plurality of noise suppression capacitors located away from the plurality of power conductive vias is less than or equal to 2 centimeters.
